(19) United States
(12) Patent Application Publication
(10) Pub. No.: US 2026/0166778 A1
(43) Pub. Date: Jun. 18, 2026

(54) Method of Wafer Separation

(71) Applicant: Wolfspeed, Inc., Durham, NC (US)

(72) Inventor: Simon Bubel, Carrboro, NC (US)

(21) Appl. No.: 18/986,027

(22) Filed: Dec. 18, 2024

(51) Int. Cl. B28D 5/00; H10D 62/60; H10D 62/832

(52) U.S. Cl. CPC B28D 5/0011; H10D 62/60; H10D 62/8325

(57) ABSTRACT

A method of removing a wide bandgap semiconductor wafer from a boule is provided. The method includes forming a modified region in the boule through diffusion or drift of a substance from a surface of the boule and separating the wide bandgap semiconductor wafer from the boule along a least a portion of the modified region.

### FIELD

The present disclosure relates generally to semiconductor workpieces and semiconductor device fabrication, and more particularly to processing of semiconductor workpieces, such as silicon carbide semiconductor boules or wafers.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III-nitride based semiconductor materials. The fabrication process for power semiconductor devices may require processing of wide bandgap semiconductor wafers, such as silicon carbide semiconductor wafers.

### SUMMARY

Aspects and advantages of embodiments of the present disclosure will be set forth in part in the following description, or can be learned from the description, or can be learned through practice of the embodiments.

One example aspect of the present disclosure is directed to a method of removing a wide bandgap semiconductor wafer from a boule. The method comprises forming a modified region in the boule through diffusion or drift of a substance from a surface of the boule and separating the wide bandgap semiconductor wafer from the boule along at least a portion of the modified region.

Another example aspect of the present disclosure is directed to a system for separating a wide bandgap semiconductor wafer from a boule. The system comprises a radiation source configured to provide a damage-inducing emission and a substance source in contact with a surface of the boule configured to transmit the substance through the surface to the subsurface damage layer to form a modified region. The damage-inducing emission is configured to induce a subsurface damage layer in a boule.

Another example aspect of the present disclosure is directed to a system for separating a wide bandgap semiconductor wafer from a boule. The system comprises an ion source configured to implant ions to a subsurface layer of a boule; and a substance source in contact with a surface of the boule configured to transmit the substance through the surface to the subsurface layer to form a modified region.

Another example aspect of the present disclosure is directed to an assembly. The assembly comprises a boule having a modified subsurface layer and a substance source in contact with a surface of the boule configured to transmit the substance through the surface to the modified subsurface layer to form a modified region.

Another example aspect of the present disclosure is directed to a semiconductor wafer comprising silicon carbide. The semiconductor wafer comprises a diffused impurity. A concentration of the diffused impurity is non-uniform along a thickness of the semiconductor wafer. A ratio of the concentration of the diffused impurity in one major surface region of the semiconductor wafer to the concentration of the diffused impurity in a central region is about 10 or more.

Another example aspect of the present disclosure is directed to a semiconductor wafer comprising silicon carbide. The semiconductor wafer comprises an impurity comprising lithium, beryllium, fluorine, sodium, magnesium, sulfur, antimony, titanium, chlorine, iron, cobalt, nickel, HNO3, NaOH, HF, KHF2, NH4F2, NH4F, SF4, SF6, NF3, CF4, SiF4, Cl2, CHF3, IBr, ICl, I2, H2O2, SiH4, lithium ions, fluorine ions, silicides, carbides, silanes, carbon oxides, protons, or a combination of two or more thereof.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 is a first perspective view crystal plane diagram showing the coordinate system for a hexagonal crystal such as 4H-SiC.

FIG. 2 is a second perspective view crystal plane diagram for a hexagonal crystal, illustrating a vicinal plane that is non-parallel to the c-plane.

FIG. 3A is a perspective view wafer orientation diagram showing orientation of a vicinal wafer relative to the c-plane.

FIG. 3B is a simplified cross-sectional view of the vicinal wafer of FIG. 3A superimposed over a portion of a boule.

FIG. 3C is a perspective view of a wafer orientation diagram showing orientation of an on-axis wafer relative to the c-plane.

FIG. 3D is simplified cross-sectional view of the wafer of FIG. 3C superimposed over a portion of a boule.

FIG. 4 is a top plan view of an exemplary silicon carbide semiconductor wafer, with superimposed arrows showing crystallographic orientation directions.

FIG. 5A is a side elevation schematic view of an on-axis boule of crystalline material.

FIG. 5B is a side elevation schematic view of the boule of FIG. 5A being rotated by 4 degrees, with a superimposed pattern for cutting end portions of the boule.

FIG. 5C is a side elevation schematic view of a boule following removal of end portions to provide end faces that are non-perpendicular to the c-direction.

FIG. 5D is a side elevation schematic view of an off-axis grown boule of crystalline material.

FIG. 5E is a side elevation schematic view of an off-axis grown boule having end faces that are non-perpendicular to the c-direction.

FIG. 6 depicts an example semiconductor boule having a modified region according to examples of the present disclosure.

FIG. 7 depicts an example semiconductor boule having a modified region according to examples of the present disclosure.

FIG. 8A depicts an overview of an example method and system according to examples of the present disclosure.

FIG. 8B depicts an overview of an example method and system according to examples of the present disclosure.

FIG. 9 depicts an overview of an example method and system according to examples of the present disclosure.

FIG. 10 depicts an overview of an example method and system according to examples of the present disclosure.

FIG. 11 depicts an example semiconductor wafer according to examples of the present disclosure.

FIG. 12 depicts a flowchart according to an example method of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Power semiconductor devices are often fabricated from wide bandgap semiconductor materials, such as silicon carbide or group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the technology according to example embodiments of the present disclosure may be used with any semiconductor material, such as other wide bandgap semiconductor materials, without deviating from the scope of the present disclosure. Example wide bandgap semiconductor materials include silicon carbide and the group III-nitrides.

Power semiconductor devices may be fabricated using epitaxial layers formed on a semiconductor workpiece, such as a silicon carbide semiconductor wafer. Aspects of the present disclosure are discussed with reference to a semiconductor workpiece that is a semiconductor wafer that includes silicon carbide (“silicon carbide semiconductor wafer”) for purposes of illustration and discussion. Those of ordinary skill in the art, using the disclosures provided herein, will understand that aspects of the present disclosure can be used with other semiconductor workpieces, such as other wide bandgap semiconductor workpieces. Other semiconductor workpieces may include carrier substrates, ingots, boules, polycrystalline substrates, monocrystalline substrates, bulk materials having a thickness of greater than 1 millimeter, such as greater than about 5 millimeters, such as greater than about 10 millimeters, such as greater than about 20 millimeters, such as greater than about 50 millimeters, such as greater than about 100 millimeters, such as greater than about 200 millimeters, etc.

In some examples, the semiconductor workpiece includes silicon carbide crystalline material. The silicon carbide crystalline material may have a 4H crystal structure, 6H crystal structure, or other crystal structure. The semiconductor workpiece can be an on-axis workpiece (e.g., end face parallel to the (0001) plane) or an off-axis workpiece (e.g., end face non-parallel to the (0001) plane).

Aspects of the present disclosure may make reference to a surface of the semiconductor workpiece. In some examples, the surface of the workpiece may be, for instance, a silicon face of the workpiece. In some examples, the surface of the workpiece may be, for instance, a carbon face of the workpiece.

In some examples, a semiconductor wafer may be a solid semiconductor workpiece upon which semiconductor device fabrication may be implemented. A semiconductor wafer may be a homogenous material, such as silicon carbide, and may provide mechanical support for the formation and/or carrying of additional semiconductor layers (e.g., epitaxial layers), metallization layers, and other layers to form one or more semiconductor devices. In some examples, a semiconductor wafer may have a thickness in a range of about 0.2 microns to about 1000 microns, or greater.

Semiconductor wafers may also include engineered substrates, in which the mechanical and other properties (e.g., thermal properties) are realized by a layered or multi-component structure with a solid semiconductor covering at least one surface.

A semiconductor wafer may be characterized by a plurality of surfaces. For example, a semiconductor wafer may have a “first major surface” and a “second major surface.” The first major surface may be generally opposite the second major surface. The first and second major surfaces may be generally parallel to one another. A semiconductor wafer may also have a “side surface” corresponding to a surface extending between the two major surfaces. For example, the side surface may extend between the first major surface and the second major surface.

Power semiconductor device fabrication processes may include surface processing operations that are performed on the silicon carbide semiconductor wafer to prepare one or more surfaces of the silicon carbide semiconductor wafer for later processing steps, such as surface implantation, formation of epitaxial layers, metallization, etc. Example surface processing operations may include grinding operations, lapping operations, and polishing operations. Methods for surface processing of semiconductor wafers in semiconductor manufacturing may include grinding, lapping, and/or polishing the rough surfaces until a sufficient smoothness and/or thickness is achieved.

Grinding is a material removal process that is used to remove material from the semiconductor wafer. Grinding may be used to reduce a thickness of a semiconductor wafer. Grinding typically involves exposing the semiconductor wafer to a surface comprising an abrasive, such as grinding teeth on a grind wheel. Grinding may remove material of the semiconductor wafer through engagement with the abrasive surface.

Lapping is a precision finishing process that uses a loose abrasive in slurry form. The slurry typically includes coarser particles (e.g., largest dimension of the particles being greater than about 100 microns) to remove material from the semiconductor wafer. Lapping typically does not include engaging the semiconductor wafer with a surface comprising an abrasive on the lapping tool (e.g., a wheel or disc having a surface comprising an abrasive). Instead, the semiconductor wafer typically comes into contact with a lapping plate or a tile usually made of metal. Lapping typically provides better planarization of the semiconductor wafer relative to grinding.

Polishing is a process to remove imperfections and create a very smooth surface with a low surface roughness. Polishing may be performed using a slurry and a polishing pad. The slurry typically includes finer particles relative to lapping, but coarser particles relative to chemical mechanical planarization (CMP). Polishing typically provides better planarization of the semiconductor wafer relative to grinding.

CMP is a type of fine or ultrafine polishing, typically used to produce a smoother surface ready, for instance, for epitaxial growth of layers on the semiconductor wafer. CMP may be performed chemically and/or mechanically to remove imperfections and to create a very smooth and flat surface with low surface roughness. CMP typically involves changing the material of the semiconductor through a chemical process (e.g., oxidation) and removing the new material from the semiconductor wafer through abrasive contact with a slurry and/or other abrasive surface or polishing pad (e.g., oxide removal). In CMP, the abrasive elements in the slurry typically remove the product of the chemical process and do not remove the bulk material of the semiconductor wafer, often leaving very low subsurface damage.

Methods for fabricating semiconductor wafers from semiconductor material boules may incur significant material losses and consumable tool losses and costs due to the structural properties of crystalline boules and current methods of separating or fracturing substrates from a boule. Methods for fabricating power semiconductor devices include forming a crystalline material boule, such as a silicon carbide boule, and separating portions of the boule to form substrates, such as silicon carbide semiconductor wafers. In some instances, boules may be formed to include doped regions with dopants within the crystalline material boule.

Methods for forming semiconductor wafers from boules may include, for instance, cutting thin layers (e.g., wafers) from the boule using wire saws. Another example removal process for forming semiconductor wafers from boules may include a laser-based removal process (e.g., laser splitting). Laser-based removal processes may include providing subsurface laser damage patterns to a boule to form weakened areas in the boule. Portions may then be separated from the boule along the weakened areas to produce semiconductor wafers. Separation processes may include, for example, ultrasonic fracturing, mechanical force fracturing, or other fracturing methods.

Processes such as laser splitting or wire sawing result in a significant loss of usable material through the creation of kerf and cause the expansion of roughness and damage below the surface that needs to be removed in subsequent processing steps. For example, the laser splitting or wire sawing processes may produce a rough and uneven surface on both the boule and the crystalline material substrates (e.g., semiconductor wafers) separated from the boule. Semiconductor devices and device manufacturing may require smooth surfaces on a semiconductor workpiece. Accordingly, in some cases, before continuing with further separations of the boule or further manufacturing with the semiconductor workpiece, the rough surface(s) may need to be subjected to surface processing operations. For instance, in some examples, the surface of the boule may be smoothed to allow for the formation of subsequent laser damage regions in the boule. Otherwise, a rough surface on the boule may lead to undesirable reflection/refraction of one or more laser(s) used during formation of the subsurface laser damage regions for removal of subsequent semiconductor wafers. Methods for surface processing of boules and substrates (e.g., semiconductor wafers) in semiconductor manufacturing may include grinding, lapping, and/or polishing the rough surfaces until a sufficient smoothness is achieved.

Some surface processing operations (e.g., grinding, lapping, polishing, etc.) may include planarizing rough or deeply grooved silicon carbide surfaces. Planar surface processing operations may expose a surface of the semiconductor wafer to a generally planar tool surface (e.g., grinding wheel, grind disc, polishing pad) for removing and/or smoothing material. The planar tool surface may remove material from “peaks” in the rough surface before removing material from deep trenches, valleys, or grooves in the rough surface. In this way, a planar surface processing operation may remove material from the semiconductor wafer and reduce surface roughness. Example planar surface processing operations include using a polishing pad, grind disc, or grind wheel.

Grinding methods may incur substantial time, material, and consumable tool loss and cost due to the structural properties of the crystalline materials used in semiconductor devices and smoothness requirements of semiconductor devices. Materials used in wide bandgap semiconductor devices, such as, for example, silicon carbide, have extreme rigidity and strength requiring expensive tools (e.g., with diamond abrasive elements) that are rapidly consumed. The grinding process also results in material losses from grinding away potentially usable material to provide a sufficiently smooth surface for semiconductor device manufacturing.

Accordingly, aspects of the present disclosure are directed to methods for processing a semiconductor workpiece, such as a silicon carbide semiconductor boule or wafer. In some embodiments, the methods provide for wafer singulation, film exfoliation, or semiconductor splitting through the formation of a modified layer below the surface of a workpiece (e.g., boule) and subsequent diffusion or drift of impurities or ions to the modified layer. The material separation can then be achieved by physical, chemical, electrochemical, or photochemical means at the modified layer and the accumulated impurities or ions. In some embodiments, material separation may be achieved via expansion of the modified layer through intercalation of impurities or ions.

In contrast to methods such as laser splitting, in which a laser treatment creates a fracture layer, the methods described herein may only need modification below the surface of the boule, such as accumulation of intrinsic defects, phase change, or amorphization. As no fracture layer is needed, the amount of energy deposited below the surface can be reduced and excessive damage creation and propagation can also be reduced. Further, splitting is initiated through material diffusion or drift from the surface, resulting in a workpiece size independent splitting time. For example, as the material diffusion or drift can be performed over the entire surface at once, the time for splitting is a function of the time it takes for the material to reach the desired depth, which is independent of the surface area of the workpiece. As such, the methods described herein are particularly useful for large area boule exfoliation or splitting of wafers with diameters in the range of or larger than 150 mm, such as 200 mm or larger.

Additionally, there is an industry trend to prefer smaller wafer thickness. As such, when using splitting methods that generate a kerf or rough surfaces that need grinding and polishing, the ratio of material loss associated with the splitting and damage removal process can be large. However, the methods disclosed herein allow for the exfoliation of thin wafers from a semiconductor boule. For example, wafer thickness can be about 350 μm or less, such as about 200 μm or less, such as about 150 μm or less, such as about 100 μm or less, such as about 50 μm or less, such as about 10 μm or less. The thickness may be about 0.2 μm or greater, such as about 1 μm or greater, such as about 50 μm or greater, such as about 100 μm or greater, such as about 200 μm or greater

In some example embodiments, the method includes forming a modified subsurface layer in a semiconductor boule at a depth below the surface at the desired splitting or exfoliation position. Impurities, ions, or defects may then be introduced or accumulated at the modified subsurface layer to form a modified region. The impurities, ions, or defects in the modified region can lead to material separation through swelling/intercalation, chemical, electrochemical, photochemical, electrostatic, or physical means that may or may not be triggered by a radiation source or electrical bias.

In some embodiments, the modified subsurface layer can be produced via a radiation source that leads to nuclear transmutation of species or accumulation of intrinsic or extrinsic defects, such as voids, dopants, or crystallographic 1d or 2d defects or that leads to breaking of bonds, recrystallization, or amorphization of a defined subsurface layer. For example, a radiation source can be a pulsed laser with a focus below the material surface. The laser deposits energy inside the material, allowing the creation of the modified layer.

In some embodiments, the modified subsurface layer can be produced via an ion implantation process. For example, a deep deposition of an impurity can be achieved by ion channeling, leveraging the crystallographic orientation of a semiconductor workpiece. As another example, ion implantation may be conducted without the effect of channeling and can create a gaussian deposition profile. The ion source may use different techniques of energy filtering to generate the intended implantation properties. Gaussian ion implantation may include energy filtering of an ion beam.

The modified region can have a shape or thickness suitable for obtaining the desired wafer shape or thickness. In some embodiments, the modified region may be an interface layer. For example, the interface layer can be a layer of modified material in a boule between two unmodified portions. For example, the interface layer can be formed by diffusion or drift of impurities or ions to a modified subsurface layer. In other embodiments, the interface layer is a boundary layer between an upper layer and a lower layer with different properties. Such different properties and boundary can be produced by epitaxial steps, impurity diffusion, radiation damage, nuclear transmutation, or material intercalation.

In some embodiments, the accumulation of an impurity at the modified region (e.g., interface layer) can be achieved by diffusion of a mobile element. For example, in silicon carbide materials, the mobile element can be lithium, hydrogen, beryllium, boron, nitrogen, fluorine, sodium, magnesium, aluminum, phosphorus, sulfur, chlorine, antimony, or transition metals such as titanium, iron, cobalt, or nickel. Diffusion may be enhanced by environmental factors such as pressure and temperature.

In some embodiments, the accumulation of an impurity can be achieved by electrostatic forces resulting in a drift of ions. For example, lithium ions may be intercalated from a boundary to an electrolyte comprising lithium, a lithium salt, or solid electrolyte. Such systems may comprise interface materials, such as LiF, LiNO₃, LIPF₆, Li₃N—LiF, LiClO₄, LiBF₄, LiTFSI, LLZTO, LFP, LiCoO₂, LiMnO₂, LiNiO₂, Li—NMC, and/or Li—NCA. In some embodiments, fluorine ions or protons may be driven to the interface or to a certain subsurface depth or region in an electrochemical setup.

In some embodiments, the separation process can be a consequence of swelling through intercalation processes or electrochemical reactions through a bias which may be the same as the bias driving the drift of the ions or may be a different bias after enough ions have accumulated in the modified region (e.g., interface layer). In some embodiments, chemical reactions can be triggered by the addition of heat or photoactivation through a radiation source. In some embodiments, such reactions include the formation of silicides or carbides.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

Methods disclosed herein may be applied to substrates of various crystalline materials, of both single crystal and polycrystalline varieties. In certain embodiments, methods disclosed herein may utilize cubic, hexagonal, and other crystal structures, and may be directed to crystalline materials having on-axis and off-axis crystallographic orientations. In certain embodiments, methods disclosed herein may be applied to semiconductor materials and/or wide bandgap materials. Example materials include, but are not limited to, silicon, gallium arsenide, and diamond.

In certain embodiments, such methods may utilize single crystal semiconductor materials having hexagonal crystal structure, such as 4H-SiC, 6H-SiC, or Group III nitride materials (e.g., GaN, AlN, InN, InGaN, AlGaN, or AlInGaN). Various illustrative embodiments described hereinafter mention SiC generally or 4H-SiC specifically, but it is to be appreciated that any suitable crystalline material may be used. Among the various SiC polytypes, the 4H-SiC polytype is particularly attractive for power electronic devices due to its high thermal conductivity, wide bandgap, and isotropic electron mobility. Bulk silicon carbide may be grown on-axis (i.e., with no intentional angular deviation from the c-plane thereof, suitable for forming undoped or semi-insulating material) or off-axis (typically departing from a grown axis such as the c-axis by a non-zero angle, typically in a range of from 0.5 to 10 degrees (or a subrange thereof such as 2 to 6 degrees or another subrange), as may be suitable for forming n-doped or highly conductive material).

Certain embodiments herein may use substrates of doped or undoped silicon carbide, such as silicon carbide boules, which may be grown by physical vapor transport (PVT) or other conventional boule fabrication methods. If doped SiC is used, such doping may render the SiC n-type or semi-insulating in character. In certain embodiments, an n-type silicon carbide boule is intentionally doped with nitrogen. In certain embodiments, an n-type silicon carbide boule includes resistivity values within a range of 0.015 to 0.028 Ohm-centimeters. In certain embodiments, a silicon carbide boule may have resistivity values that vary with vertical position, such that different substrate portions (e.g., wafers) have different resistivity values, which may be due to variation in bulk doping levels during boule growth.

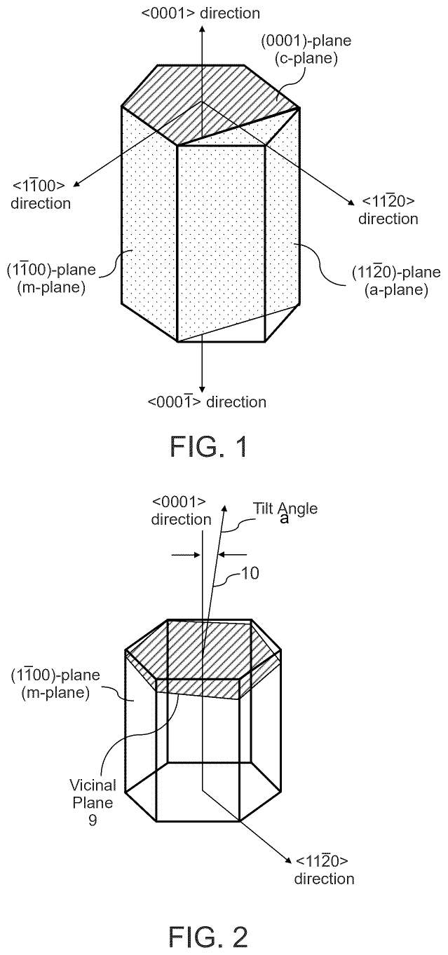

FIG. 1 is a first perspective view crystal plane diagram showing the coordinate system for a hexagonal crystal such as 4H-silicon carbide (“SiC”), in which the c-plane (0001) is perpendicular to both the m-plane (11̅00) and the a-plane (112̅0). The c-plane is perpendicular to the <0001> direction. The m-plane (11̅00) is perpendicular to the <11̅00> direction. The a-plane (112̅0) is perpendicular to the <112̅0> direction. The <0001̅> direction is opposite the <0001> direction.

FIG. 2 is a second perspective view crystal plane diagram for a hexagonal crystal, illustrating a vicinal plane 9 that is non-parallel to the c-plane, wherein a vector 10 (which is normal to the vicinal plane 9) is tilted away from the <0001> direction by a tilt angle α, with the tilt angle α being inclined (slightly) toward the <112̅0> direction.

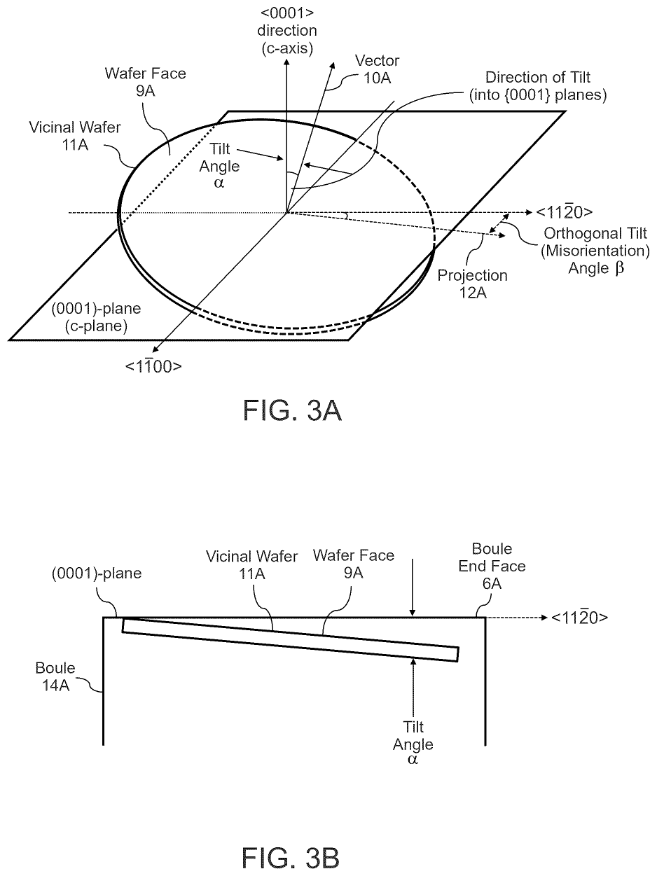

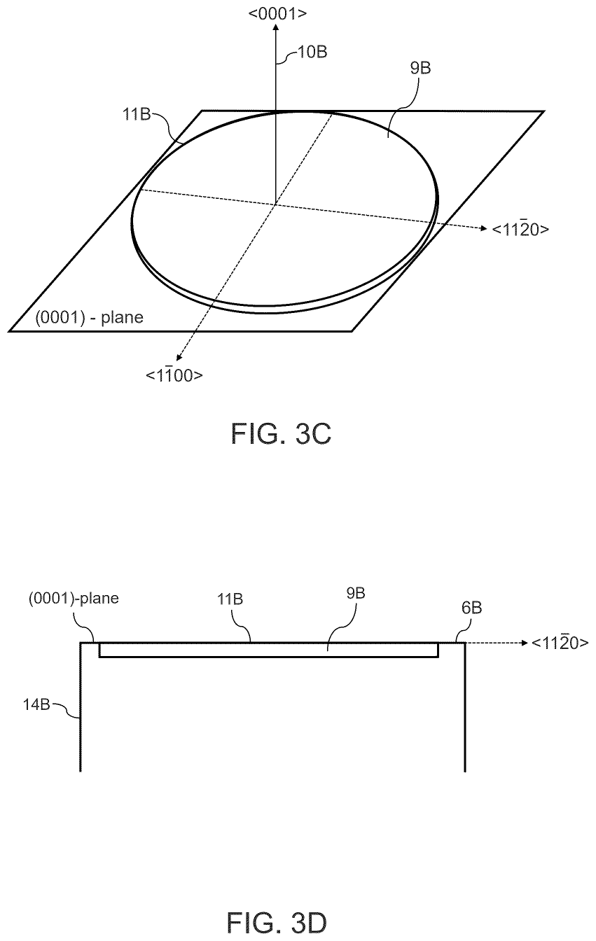

FIG. 3A is a perspective view of a wafer orientation diagram showing orientation of a vicinal wafer 11A relative to the c-plane (0001), in which a vector 10A (which is normal to the wafer face 9A) is tilted away from the <0001> direction by a tilt angle α. An orthogonal tilt (or misorientation angle) β may span between the <112̅0>direction and the projection of vector 10A onto the c-plane. FIG. 3B is a simplified cross-sectional view of the vicinal wafer 11A superimposed over a portion of a boule 14A (e.g., an on-axis boule having an end face 6A parallel to the (0001) plane) from which the vicinal wafer 11A was defined. FIG. 3B shows that the wafer face 9A of the vicinal wafer 11A is misaligned relative to the (0001) plane by a tilt angle α.

FIG. 3C is a perspective view of wafer orientation diagram showing orientation of an on-axis wafer 11B relative to the c-plane (0001), in which a vector 10B (which is normal to the wafer face 9B) is parallel to the <0001> direction. FIG. 3D is a simplified cross-sectional view of the wafer 11B superimposed over a portion of a boule 14B (e.g., an on-axis boule having an end face 6B parallel to the (0001) plane). FIG. 3D shows that the wafer face 9B of the on axis-wafer 11B is aligned with the (0001) plane.

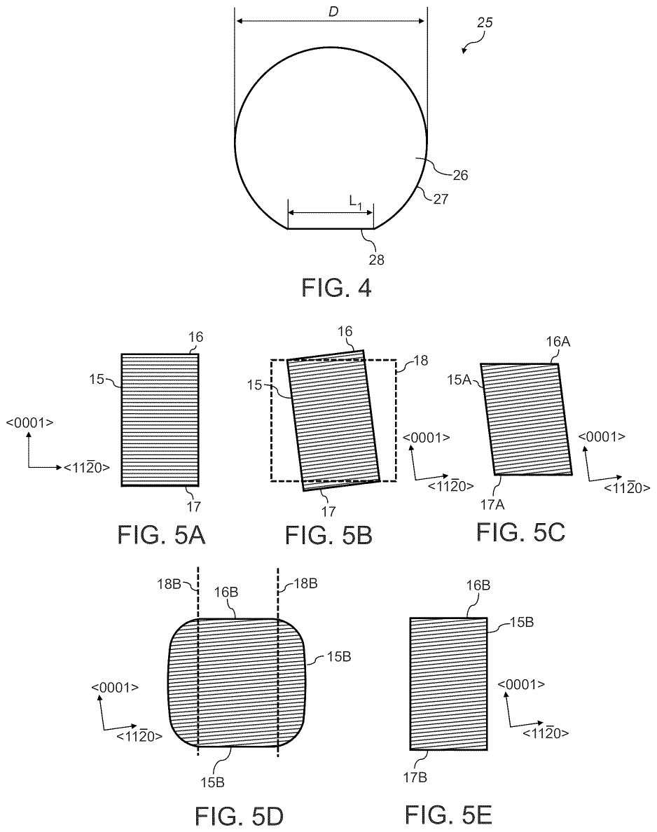

FIG. 4 is a top plan view of an example silicon carbide semiconductor wafer 25 including an upper face 26. The silicon carbide semiconductor wafer 25 may include a surface that is misaligned with (e.g., off-axis at an oblique angle relative to) the c-plane. The silicon carbide semiconductor wafer 25 may be laterally bounded by a generally round edge 27 (having a diameter D) including a primary flat 28 (having a length L₁) that is perpendicular, for instance, to the (112̅0) plane. In some instances, the wafer 25 may include a notch instead of a primary flat.

Methods disclosed herein may be applied to substrates of various crystalline materials, of both single crystal and polycrystalline varieties. In certain embodiments, methods disclosed herein may utilize cubic, hexagonal, and other crystal structures, and may be directed to crystalline materials having on-axis and off-axis crystallographic orientations. In certain embodiments, methods disclosed herein may be applied to semiconductor materials and/or wide bandgap materials. Example materials include, but are not limited to, silicon, gallium arsenide, and diamond.

In certain embodiments, such methods may utilize single crystal semiconductor materials having a hexagonal crystal structure, such as 4H-SiC, 6H-SiC, or Group III-nitride materials (e.g., GaN, AlN, InN, InGaN, AlGaN, or AlInGaN). Various illustrative embodiments described hereinafter mention SiC generally or 4H-SiC specifically, but it is to be appreciated that any suitable crystalline material may be used. Among the various SiC polytypes, the 4H-SiC polytype is particularly attractive for power electronic devices due to its high thermal conductivity, wide bandgap, and isotropic electron mobility. Bulk silicon carbide may be grown on-axis (i.e., with no intentional angular deviation from the c-plane thereof, suitable for forming undoped or semi-insulating material) or off-axis (typically departing from a grown axis such as the c-axis by a non-zero angle, typically in a range of from 0.5 to 10 degrees (or a subrange thereof such as 2 to 6 degrees or another subrange), as may be suitable for forming n-doped or highly conductive material). Semiconductor wafers may also include engineered substrates, in which the mechanical and other properties (e.g., thermal properties) are realized by a layered or multi-component structure with a solid semiconductor covering at least one surface.

Certain embodiments herein may use substrates of doped or undoped silicon carbide, such as silicon carbide boules, which may be grown by physical vapor transport (PVT) or other conventional boule fabrication methods. If doped SiC is used, such doping may render the SiC n-type or semi-insulating in character. In certain embodiments, an n-type silicon carbide boule is intentionally doped with nitrogen. In certain embodiments, an n-type silicon carbide boule includes resistivity values within a range of 0.015 to 0.028 Ohm-centimeters. In certain embodiments, a silicon carbide boule may have resistivity values that vary with vertical position, such that different substrate portions (e.g., wafers) have different resistivity values, which may be due to variation in bulk doping levels during boule growth. In certain embodiments, a silicon carbide boule may have doping levels that vary horizontally, from a higher doping region proximate to a center of the boule to a lower doping level proximate to a lateral edge thereof.

FIGS. 5A and 5C schematically illustrate on-axis and off-axis crystalline substrates in the form of boules that may be utilized with methods disclosed herein. FIG. 5A is a side elevation schematic view of an on-axis boule 15 of crystalline material having first and second end faces 16, 17 that are perpendicular to the c-direction (i.e., <0001> direction for a hexagonal crystal structure material such as 4H-SiC). FIG. 5B is a side elevation schematic view of the boule 15 of FIG. 5A being rotated by four degrees, with a superimposed pattern 18 (shown in dashed lines) for cutting and removing end portions of the boule 15 proximate to the end faces 16, 17. FIG. 5C is a side elevation schematic view of an off-axis boule 15A formed from the boule 15 of FIG. 5B, following removal of end portions to provide new end faces 16A, 17A that are non-perpendicular to the c-direction. Aspects of the present disclosure are applicable to both on-axis boules 15 and/or off-axis boules 15A or other on-axis crystalline materials and/or off-axis crystalline materials.

FIGS. 5D and 5E schematically illustrate off-axis grown boules that may be utilized with methods disclosed herein. FIG. 5D is a side elevation schematic view of an off-axis grown boule 15B of crystalline material (e.g., grown from an off-axis seed material) having first and second end faces 16B and 17B that are non-perpendicular to the c-direction (e.g., <0001> direction for a hexagonal crystal structure material such as 4H-SiC). Portions of the boule 15B may be cut along the superimposed pattern 18B (shown in dashed lines) to provide the off-axis boule 15B shown in FIG. 5E. Off-axis semiconductor wafers may be provided from the off-axis boule 15E by cutting or otherwise removing the wafers from the boule 15B in a manner parallel to the faces 16B, 17B.

Aspects of the present disclosure are directed to providing semiconductor wafers from any suitable boule, such as an on-axis boule, an off-axis boule, an on-axis grown boule, and off-axis grown boule, a boule grown along other directions or axes (e.g., a-axis, c-axis) or other suitable boule.

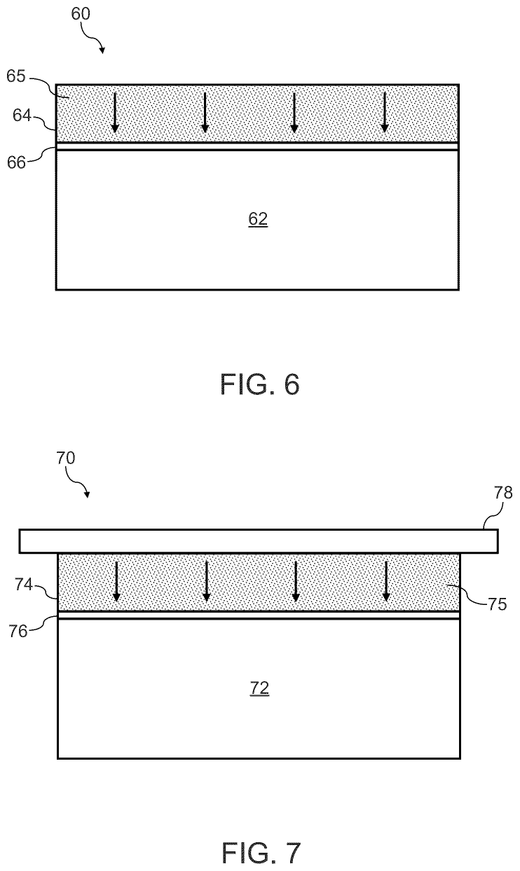

As mentioned above, separating a semiconductor wafer from a boule can involve forming a modified region, such as an interface layer. FIG. 6 illustrates a semiconductor boule 60 having a modified region 64. In the modified region 64, impurities 65 are diffusing toward modified subsurface layer 66, which may be a laser-induced subsurface damage layer created at controlled depth based on the desired thickness of the semiconductor wafer to be separated. The impurities may be diffusing from a source or reservoir (not shown). As shown, the modified subsurface layer 66 can prevent the impurities 65 from diffusing further through the boule 60, leaving an unmodified portion below. As a result, the impurities may accumulate at the modified subsurface layer, creating an interface layer at the boundary between the modified region and the unmodified region. A semiconductor wafer can then be separated from the boule at the interface layer, as described in further detail below.

FIG. 7 illustrates a semiconductor boule 70 having a modified region 74. In the modified region 74, charged impurities (e.g., ions) 75 are drifting toward modified subsurface layer 76, which may be a laser-induced subsurface damage layer created at controlled depth based on the desired thickness of the semiconductor wafer to be separated. The charged impurities may be diffusing from a source or reservoir (not shown). A bias source 78 may drive the charged impurities 75 into the boule 70 by an electrostatic force. As shown, the modified subsurface layer 76 can prevent the charged impurities 75 from diffusing further through the boule 70, leaving an unmodified portion below. As a result, the impurities may accumulate at the modified subsurface layer, creating an interface layer at the boundary between the modified region and the unmodified region. A semiconductor wafer can then be separated from the boule at the interface layer, as described in further detail below.

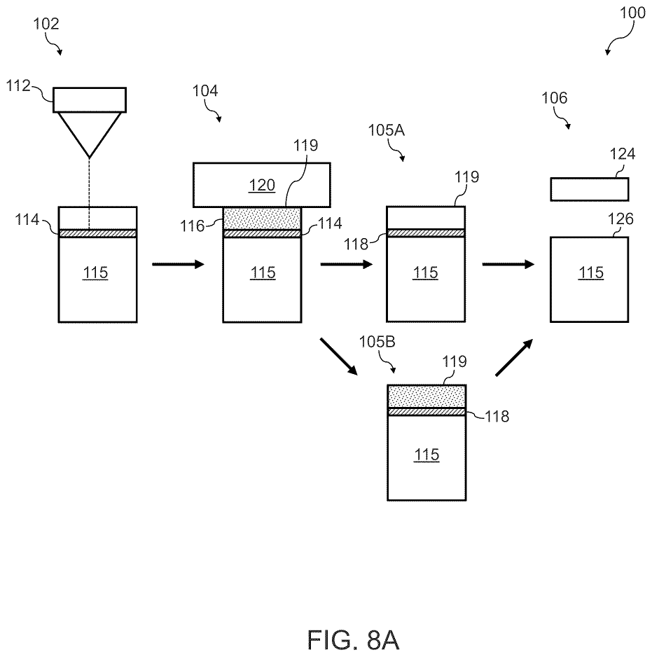

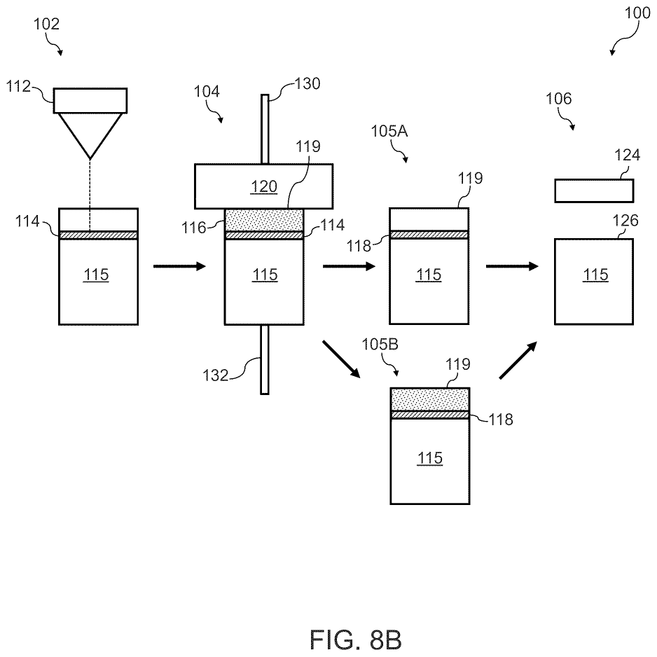

FIG. 8A depicts an overview of an example method 100 according to example embodiments of the present disclosure. FIG. 8A is intended to represent structures for identification and description and is not intended to represent the structures to physical scale. The method 100 includes operations illustrated in a particular order for purposes of illustration and discussion. Those of ordinary skill in the art, using the disclosures provided herein, will understand that the various steps or operations of the method may be adapted, rearranged, omitted, include steps not illustrated, and/or modified in various ways without deviating from the scope of the present disclosure.

At 102, the method 100 may include providing a semiconductor boule 115 with a modified subsurface layer 114. The modified subsurface layer 114 may be the result of an induced subsurface damage process performed on the semiconductor boule 115. The induced subsurface damage process may be a laser-based removal process or other induced subsurface damage process (e.g., ion implantation induced subsurface damage process). For instance, in some examples, one or more damage-inducing energy sources 112 (e.g., a radiation source or an ion beam) may be operated to provide a damage-inducing emission of radiation or ions to induce a modified subsurface layer 114 in the semiconductor boule 115.

In some embodiments, the modified subsurface layer 114 is formed by creating an induced damage region that is generally parallel to the upper surface of the semiconductor boule, or the implementation of a subsurface layer below the upper surface of the semiconductor boule 115 at a targeted depth. The induced damage region may be created by one or more passes of an emission of radiation, such as the emission of a laser, to induce subsurface damage at a target depth below the upper surface of the boule.

In some embodiments, the subsurface damage layer may be created by ion (or other species) implantation. For example, in an ion implantation process, dopant ions can be accelerated to a high energy and directed towards the semiconductor surface by an ion beam. The implants penetrate the surface and come to rest at a depth dependent on the energy and angle with respect to the crystal orientation.

In some embodiments, particularly when a relatively deep depth is desired, the subsurface damage layer may be formed using ion channeling. In general, channeling occurs in silicon carbide when the direction of implantation is within about 2° of a crystallographic axis of the silicon carbide crystal. When the direction of implantation is more than about 2° of a crystallographic axis of the silicon carbide crystal, the atoms in the lattice appear to be randomly distributed relative to the direction of implantation, which reduces channeling effects. As used herein, the term “implant angle” refers to the angle between the direction of implantation and a crystallographic axis, such as the c-axis or <0001> axis, of the semiconductor layer into which ions are implanted. Thus, an implant angle of less than about 2° relative to the c-axis of a silicon carbide layer is expected to result in channeling.

In some examples, the damage inducing radiation source may be one or more laser sources that provide the emission of the radiation to the modified subsurface layer of the boule. In some examples, the laser treatment process may be conducted by one or more laser sources in the infrared, visible, and/or the ultraviolet range of the electromagnetic spectrum. In some examples, the one or more laser sources may be operated in continuous or pulsed modes. In some examples, the one or more radiation sources may be operable with an average power from about 1 to about 500 W, such as about 1 to about 100 W, such as about 5 W to about 30 KW, such as about 200 W to about 300 W. In some examples, the one or more radiation sources may be operable with continuous power supplied or with a frequency of about 0.1 kHz to about 20 MHz. The one or more radiation sources may include coherent radiation sources, such as electric gas discharge lasers (e.g., a gas discharge radiation source where a fraction of emitted electromagnetic radiation is amplified), metal vapor lasers (e.g., a copper vapor lasing medium), yttrium aluminum garnet (YAG) lasers including doped YAG lasers (e.g., Nd:YAG or Yb:YAG), fiber lasers (e.g., ytterbium doped glass) or rod lasers (e.g., chromium doped chrysoberyl), diode lasers (e.g., GaN, GaAs, and/or diode lasers comprising InP). The one or more radiation sources may be operated in a manner that allows nonlinear frequency conversion (e.g., frequency doubling or tripling) to meet absorption and/or optical requirements of the workpiece. The one or more radiation sources may additionally include optical means to modify the angle of incidence of the emission of radiation relative to the surface of the boule, or otherwise modify the emission of radiation, which may produce tuned irradiance profiles of the emission along a propagation distance.

In some examples, the radiation source may be one or more gas discharge sources that provide the emission of the radiation to the modified subsurface layer of the boule. The gas discharge treatment process may include exposure to electromagnetic radiation generated by low or high pressure ionization of xenon, carbon dioxide, mercury, or sodium in a gaseous form.

In some examples, the radiation source may be one or more incandescent radiation sources that provide the emission of the radiation to the modified subsurface layer of the boule. The incandescent radiation treatment process may include a filament-based radiation source and/or a halogen cycle (e.g., a halogen tungsten lamp). The incandescent radiation source may be operable in a range of about 5 watts to about 30,000 watts, such as about 5 watts to about 500 watts, or about 0.5 kilowatts to about 20 kilowatts. The incandescent radiation treatment process may include optical elements to tune optical energy (e.g., optical elements that steer, shape, or focus radiation such as lenses, mirrors, collimators, etc.) from the incandescent radiation source.

In some examples, the radiation source may be one or more electroluminescence emitters that provide the emission of the radiation to the modified subsurface layer of the boule. The electroluminescence emitter treatment process may include one or more light emitting diodes (LEDs) operable in a range of about 5 watts to about 30,000 watts, such as about 5 watts to about 500 watts, or about 0.5 kilowatts to about 30 kilowatts. The electroluminescence radiation treatment process may include optical elements to tune optical energy (e.g., optical elements that steer, shape, or focus radiation such as lenses, mirrors, collimators, etc.) from the incandescent radiation source.

In some examples, the radiation source may be one or more electronic or magnetic oscillators that provide the emission of the radiation to the modified subsurface layer of the boule. The electronic or magnetic treatment process may include a high-vacuum tube operable to generate and/or amplify electromagnetic radiation resulting from interactions of electrons within the tube. The electromagnetic radiation may encompass radio wavelengths, terahertz wavelengths, or microwave wavelengths, such as electromagnetic radiation that ranges from about 0.1 millimeters to about 1 meter.

In some examples, the radiation source may be one or more free electron resonators that provide the emission of the radiation to the modified subsurface layer of the boule. The free electron resonator treatment process may include treatment with coherent radiation resulting from electron beam propagation through a magnetic field.

In some examples, the radiation source may be one or more x-ray emitters that provide the emission of the radiation to the modified subsurface layer of the boule. The x-ray emitter treatment process may include the generation of electromagnetic radiation (e.g., x-rays) resulting from the bombardment of high-speed electrons with a target material. The resulting electromagnetic radiation may be a result of electrons bound with the target material falling into lower energy states.

In some examples, the radiation source may be one or more bremsstrahlung emitters that provide the emission of the radiation to the modified subsurface layer of the boule. The bremsstrahlung treatment process may include the generation of electromagnetic radiation (e.g., x-rays) resulting from an abrupt velocity change due to a collision or other scattering event of an electron interacting with an atomic nucleus.

The modified subsurface layer 114 may comprise voids, dopants, crystallographic 1d or 2d defects, broken bonds, recrystallized material, or amorphized material as a result of the irradiation or ion implantation process.

Referring to FIG. 8A at 104, the method 100 may include contacting the top surface 119 of the boule 115 with a source (e.g., reservoir) 120 of a substance 116. The substance 116 may comprise an impurity that is driven to the modified subsurface layer 114 through diffusion or drift. For example, in some embodiments, the substance 116 may be driven by diffusion due to the difference in concentration of the substance at the top surface 119 and the bulk of the boule 115. The modified subsurface layer 114 may act as a barrier to further diffusion so that the substance 116 accumulates at the modified subsurface layer 114. In some embodiments, the substance 116 is driven by an electrostatic or electrochemical force from the top surface 119 into the bulk of the boule 115. The modified subsurface layer 114 may act as a barrier or attraction force for the substance 116 such that it accumulates at the modified subsurface layer 114. In some embodiments, the reservoir 120 may be a gas, salt, or metal comprising the substance 116. Although depicted as a generic block, it should be understood that the reservoir 120 can have any shape such that the top surface 119 of the boule 115 is in contact with the substance 116 contained in the reservoir 120. In some embodiments, the substance 116 includes lithium, hydrogen, beryllium, boron, antimony, nitrogen, fluorine, sodium, magnesium, aluminum, phosphorus, sulfur, chlorine, titanium, iron, cobalt, nickel, HNO₃, NaOH, HF, KHF₂, NH₄F₂, NH₄F, SF₄, SF₆, NF₃, CF₄, SiF₄, Cl₂, CHF₃, IBr, ICl, I₂, H₂O₂, SiH₄, or a combination of two or more thereof.

In some embodiments, particularly when applying electrostatic or electrochemical force, the substance 116 may comprise ions or protons. Examples of suitable ions include fluorine ions and lithium ions. In some embodiments, lithium ions are driven from a liquid or solid electrolyte interface to the SiC surface. The electrolyte may comprise LiF, LIPF₆, Li₃N—LiF, LiClO₄, LiBF₄, LiTFSI, LLZTO, LFP, LiCoO₂, Li—NMC, Li—NCA, lithium salts, or a combination of two or more thereof. Electrolytes comprising protons can comprise acid solutions, perovskites, nafion, imidazolium, methanesulfonate, and related organic ionic plastic crystals. The interface to a metal ion source may supply other elements and their ions, such as beryllium, boron, antimony, nitrogen, fluorine, sodium, magnesium, aluminum, phosphorus, sulfur, chlorine, titanium, iron, cobalt, and nickel.

As shown in FIG. 8B, the substance 116 may be driven using one or more electrodes 130, 132. For example, in some embodiments, particularly when employing an electrolyte or driving ions by an electrostatic force, an electrode 130 may be in contact with the reservoir (e.g., electrolyte) 120. Optionally, a counter electrode 132 may be in contact with a portion of the boule 115. When used, the counter electrode may be in contact with the bottom portion of the boule 115, the modified subsurface layer 114, or the top portion of the boule above the modified subsurface layer 114 that will become the separated wafer. The exact design of the element establishing the electric contact (e.g., electrode) may be any known in the art and may depend on the electrolyte or metal interface being liquid or solid.

After the substance 116 diffuses or drifts to the modified subsurface layer 114, a modified region, such as interface layer 118 is formed. The interface layer 118 can be a discreet layer that exists at the same location as the modified subsurface layer 114 and has unmodified portions of the boule 115 below and above. Such an embodiment is shown as 105A in FIG. 8A. Alternatively, the interface layer 118 can be a boundary between an unmodified portion of the boule 115 and a modified portion of the boule 115. For example, the modified portion may extend from the top surface 119 of the boule to the depth of the modified subsurface layer 114. Such an embodiment is shown as 105B in FIG. 8A. For example, the modified portion may comprise the substance 116 while the unmodified portion does not. It should be understood that the unmodified portion may comprise a small amount of the substance 116, but in a much smaller concentration (e.g., less than 10% of the concentration in the modified portion). A concentration gradient of the substance 116 may also exist between the top surface 119 and the interface layer 118. The concentration may be higher at the top surface 119 or at the interface layer 118.

At 106, the method 100 may include separating a semiconductor wafer 124 from the remaining portion of the boule 115 at the interface layer. In some embodiments, the separation may occur from the diffusion or drift of the substance alone, without requiring any further active steps. For example, the separation may occur from swelling at the interface layer due to intercalation of the substance or reaction (e.g., to silicides or carbides). The swelling may cause the boule to crack and separate at this layer. In other embodiments, an additional step may be required to separate the wafer from the boule at the interface. For example, in some embodiments, separation can be triggered by heating. For example, heating may cause expansion, a phase change (e.g., evaporation, melting, sublimation, etc.), or a chemical reaction of a material at the interface layer which causes the wafer to separate from the boule. In some embodiments, separation can be triggered by an electrochemical reaction by applying a bias, which may be the same or different from an electrochemical process used to cause ion drift to the modified subsurface layer. In some embodiments, separation can be triggered by irradiating the interface layer, triggering a photochemical reaction or causing the material at the interface layer to heat. In some embodiments, separation may be triggered by a solid state chemical reaction, such as the formation of silicides, carbides, silane, or carbon oxides.

Further processing may be performed on either the semiconductor wafer 124 or the remaining portion of the boule 115. Further processing operations (e.g., etching, electrochemical etching, laser ablation, grinding, polishing, lapping, CMP, and the like) may remove portions of the exposed surface and/or provide a smoother surface suitable for later fabrication operations. The separation process may also improve process integration. For example, for an electrochemical intercalation process, electrochemical etching may be done in the same setup.

By processing the exposed surface 126 of the remainder of the boule 115, the remainder of the boule 115 may be suitable to be reused for subsequent wafer separation processes.

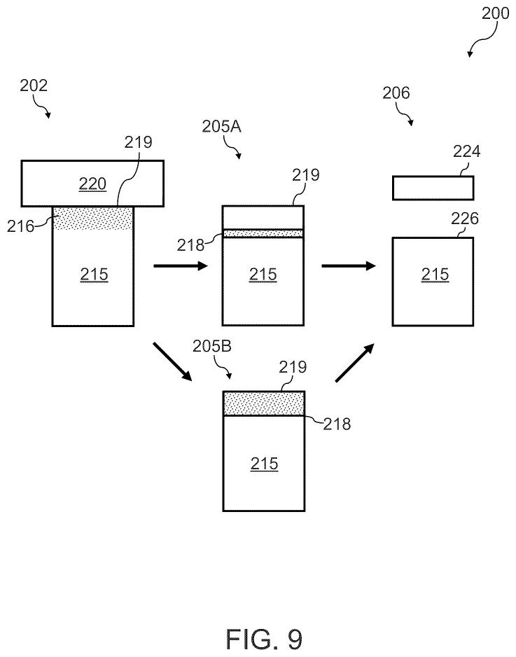

FIG. 9 depicts an overview of an example method 200 according to example embodiments of the present disclosure. FIG. 9 is intended to represent structures for identification and description and is not intended to represent the structures to physical scale. The method 200 includes operations illustrated in a particular order for purposes of illustration and discussion. Those of ordinary skill in the art, using the disclosures provided herein, will understand that the various steps or operations of the method may be adapted, rearranged, omitted, include steps not illustrated, and/or modified in various ways without deviating from the scope of the present disclosure.

At 202, the method 200 may include contacting the top surface 219 of the boule 215 with a reservoir 220 of a substance 216. The substance 216 may comprise an impurity that is driven below the top surface 219 through diffusion or drift. For example, in some embodiments, the substance 216 may be driven by diffusion due to the difference in concentration of the substance at the top surface 219 and the bulk of the boule 215. In some embodiments, the substance 216 is driven by an electrostatic or electrochemical force from the top surface 219 into the bulk of the boule 215. As method 200 does not comprise a modified subsurface layer as in method 100 described above, the depth that the impurity reaches can be controlled based on the diffusion or drift rate and the time that the diffusion or drift is performed. The depth of the diffusion or drift, and therewith the separation layer thickness, can also be adjusted by changing an external stimulus for the drift or diffusion. That could be a radiation source, an electrical or magnetic field, or removal or cut-off of the supply of the diffusing substance. The reservoir and substance may be any of those described above with respect to method 100.

After the substance 216 diffuses or drifts below the top surface 219 of the boule 215 to the desired depth, a modified region, such as interface layer 218 is formed. The interface layer 218 can be a discreet layer that has unmodified portions of the boule 215 below and above. Such an embodiment is shown as 205A in FIG. 9. As mentioned above, the unmodified portions of the boule may still have a small concentration of the substance or impurity. Alternatively, the interface layer 218 can be a boundary between an unmodified portion of the boule 215 and a modified portion of the boule 215. For example, the interface layer may extend from the top surface 219 of the boule 215 to the depth that the substance 216 diffused or drifted to. Such an embodiment is shown as 205B in FIG. 9. A concentration gradient of the substance 216 may also exist between the top surface 219 and the interface layer 218. The concentration may be higher at the top surface 219 or at the interface layer 218.

At 206, the method 200 may include separating a semiconductor wafer 224 from the remaining portion of the boule 215 at the interface layer. Separation can occur or be triggered by any of the mechanisms described above with respect to method 100.

Further processing may be performed on either the semiconductor wafer 224 or the remaining portion of the boule 215. Further processing operations (e.g., etching, electrochemical etching, laser ablation, grinding, polishing, lapping, CMP, and the like) may remove portions of the exposed surface and/or provide a smoother surface suitable for later fabrication operations.

By processing the exposed surface 226 of the remainder of the boule 215, the remainder of the boule 215 may be suitable to be reused for subsequent wafer separation processes.

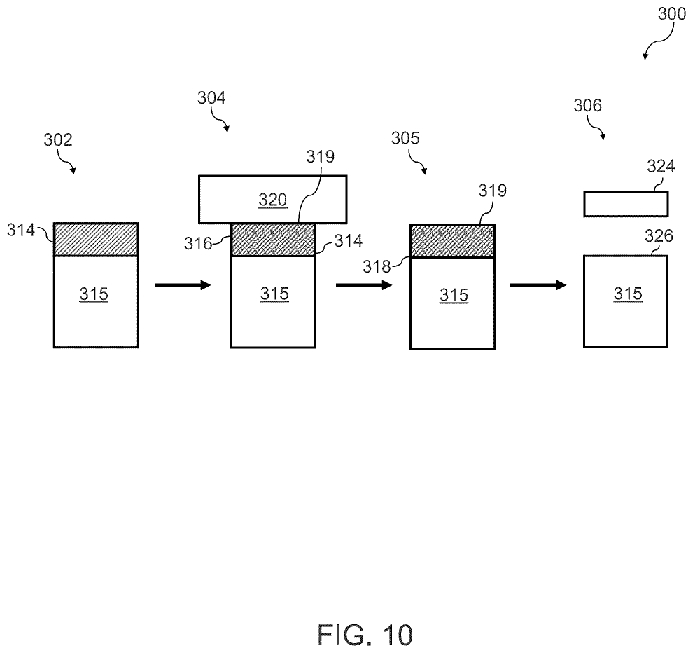

FIG. 10 depicts an overview of an example method 300 according to example embodiments of the present disclosure. FIG. 10 is intended to represent structures for identification and description and is not intended to represent the structures to physical scale. The method 300 includes operations illustrated in a particular order for purposes of illustration and discussion. Those of ordinary skill in the art, using the disclosures provided herein, will understand that the various steps or operations of the method may be adapted, rearranged, omitted, include steps not illustrated, and/or modified in various ways without deviating from the scope of the present disclosure.

At 302, the method 300 may include providing a semiconductor boule 315 with a modified subsurface layer 314. As shown in FIG. 10, the modified subsurface layer extends from the top surface 319 of the boule 315 to a certain depth below the top surface 319. The depth can be selected based on the desired thickness of the resulting wafer to be separated from the boule 315. The modified subsurface layer 314 may be formed by epitaxial steps, impurity diffusion, radiation damage, or material intercalation. For example, in some embodiments, the modified subsurface layer 314 may be formed as an epitaxial growth layer of silicon carbide or another semiconductor material on the top surface 319 of the boule 315. In some embodiments, the modified subsurface layer 314 may be formed by intercalation or diffusion of an impurity, such as any of those described above with respect to forming the interface layer, through the top surface 319 of the boule 315. In some embodiments, the modified subsurface layer 314 may be formed by radiation damage. The radiation source may include any of those described above with respect to FIG. 8A. However, rather than forming a discrete subsurface damage layer between two unmodified portions of the boule, as in FIG. 8A, the radiation damage in method 300 may cover a portion from the top surface 319 of the boule 315 to a desired depth below the top surface 319.

At 302, the method 300 may include contacting the top surface 319 of the boule 315 with a reservoir 320 of a substance 316. The substance 316 may comprise an impurity that is driven below the top surface 319 through diffusion or drift. For example, in some embodiments, the substance 316 may be driven by diffusion due to the difference in concentration of the substance at the top surface 319 and the bulk of the boule 315. In some embodiments, the substance 316 is driven by an electrostatic or electrochemical force from the top surface 319 into the bulk of the boule 315. The substance may accumulate within the modified subsurface layer 314. The reservoir and substance may be any of those described above with respect to method 100.

As the substance 316 accumulates within the subsurface damage layer 314, a modified region, such as interface layer 318 is formed at the boundary between the modified subsurface layer 314 and the unmodified portion of the boule 315 below. For example, the interface layer 318 may extend from the top surface 219 of the boule 215 to the depth that the substance 216 diffused or drifted to, which may also be at the same depth reached by the modified subsurface layer 314. The interface layer can be seen at 305 in FIG. 10. A concentration gradient of the substance 216 may also exist between the top surface 319 and the interface layer 318. The concentration may be higher at the top surface 319 or at the interface layer 318.

At 306, the method 300 may include separating a semiconductor wafer 324 from the remaining portion of the boule 315 at the interface layer. Separation can occur or be triggered by any of the mechanisms described above with respect to method 100.

Further processing may be performed on either the semiconductor wafer 324 or the remaining portion of the boule 315. Further processing operations (e.g., etching, electrochemical etching, laser ablation, grinding, polishing, lapping, CMP, and the like) may remove portions of the exposed surface and/or provide a smoother surface suitable for later fabrication operations.

By processing the exposed surface 326 of the remainder of the boule 315, the remainder of the boule 315 may be suitable to be reused for subsequent wafer separation processes.

In any of methods described herein, a permeable material may be placed between the reservoir and the top surface of the boule. The permeable material may be permeable to the substance to be transferred to the boule. For example, the material may be permeable to ions or fluids (e.g., gasses or liquids) that are intended to be transferred to the boule. Additionally, any of the process steps (e.g., forming a modified subsurface layer, forming an interface layer, or separating the wafer) may be performed in any suitable environment. For example, they may be performed at elevated temperature and/or pressure if desired.

In any of the methods described herein, the boule and resulting semiconductor wafer may have a relatively large diameter, such as from about 150 mm to about 314 mm. As explained above, the time it takes for each wafer separation process as described herein is independent of the surface area of the wafer. Therefore, the methods are particularly useful for such large diameter wafers.

The thickness of the separated wafers can be relatively thin. For example, the separated wafers may have a thickness of about 500 μm or less, such as about 400 μm or less, such as about 350 μm or less, such as about 200 μm or less, such as about 150 μm or less, such as about 100 μm or less, such as about 50 μm or less, such as about 10 μm or less. The thickness may be about 0.2 μm or greater, such as about 1 μm or greater, such as about 50 μm or greater, such as about 100 μm or greater, such as about 200 μm or greater.

The resulting semiconductor wafer may comprise some amount of the impurities introduced or accumulated (e.g., diffused impurities) during the separation process. In some embodiments, for example, the impurity may comprise lithium, hydrogen, beryllium, boron, antimony, nitrogen, fluorine, sodium, magnesium, aluminum, phosphorus, sulfur, chlorine, iron, cobalt, nickel, HNO3, NaOH, HF, KHF2, NH4F2, NH4F, SF4, SF6, NF3, CF4, SiF4, Cl2, CHF3, IBr, ICl, I2, H2O2, SiH4, or a combination of two or more thereof. In some embodiments, the impurity may comprise ions, such as lithium or fluorine ions. In some embodiments, the impurity may comprise protons. In some embodiments, the impurity may comprise silicides, carbides, silane, or carbon oxides.

In some embodiments, the concentration of the diffused impurities may be non-uniform along the thickness of the resulting wafer. For example, in some embodiments, the concentration of the diffused impurity may be higher in one major surface region of the semiconductor wafer than in an opposite major surface region. In some embodiments, the concentration of the diffused impurity may be higher in one or both major surface regions of the semiconductor wafer than in a central region. As used herein, a major surface region means a portion of the semiconductor wafer including a major surface as defined above and a portion of the semiconductor wafer adjacent to that major surface. For example, the adjacent portion may extend from the major surface to about 50%, such as to about 40%, such as to about 30%, such as to about 20%, such as to about 10% of the thickness of the wafer. The central region exists between the two major surface regions.

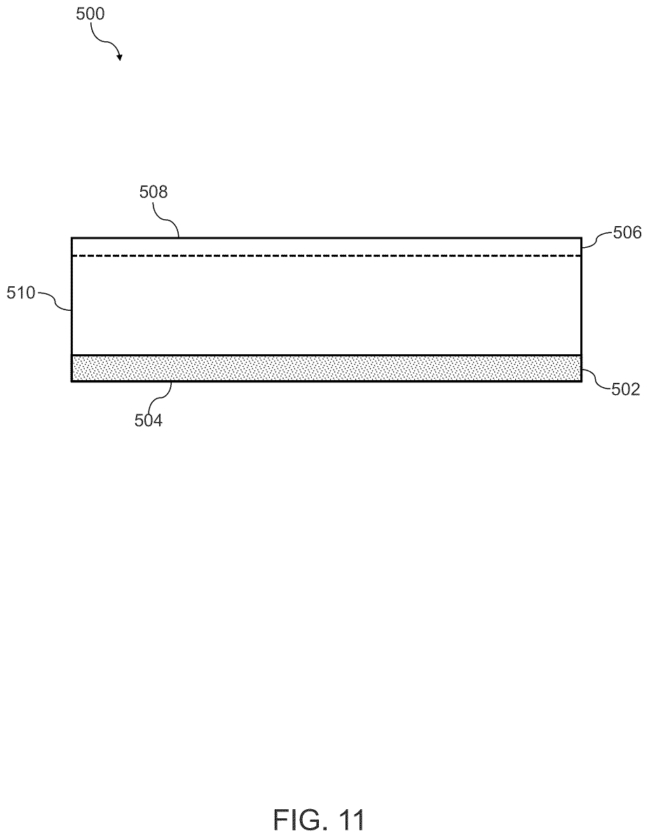

FIG. 11, for example, shows a semiconductor wafer 500 having a first major surface region 502 comprising an impurity. The first major surface region comprises major surface 504 and an adjacent portion extending less than 50% of the thickness of the wafer. The semiconductor wafer 500 also comprises a second major surface region 506 including major surface 508 and an adjacent portion extending less than 50% of the thickness of the wafer, which does not comprise the impurity at a reasonably detectable amount. The semiconductor wafer also comprises a central region 510 which also does not comprise an impurity at a reasonably detectable amount.

In some embodiments, a ratio of the concentration of the diffused impurity in one major surface region (e.g., 502) to the concentration of the diffused impurity in the opposite major surface region (e.g., 506) may be about 2 or more, such as about 5 or more, such as about 10 or more, such as about 20 or more, such as about 50 or more, such as about 100 or more. In some embodiments, one major surface region may have an impurity level not detectable at a reasonable amount while the opposite major surface region comprises the impurity.

In some embodiments, a ratio of the concentration of the diffused impurity in one or both major surface regions (e.g., 502 and/or 506) to the concentration of the diffused impurity in the central region (e.g., 510) may be about 2 or more, such as about 5 or more, such as about 10 or more, such as about 20 or more, such as about 50 or more, such as about 100 or more. In some embodiments, one or both major surface regions may comprise the impurity, while the central region has an impurity level not detectable at a reasonable amount. For instance, when the method described herein is used to separate sequential wafers from a boule, the wafers may comprise remnant impurities toward a top surface from separation of the previous wafer and in the bottom portion from separation of the subject wafer.

A system for separating a wide bandgap semiconductor wafer from a boule is also disclosed. In some embodiments, the system comprises one or more radiation sources configured to induce a subsurface damage layer in a boule. An example radiation source may be any of those described with respect to the one or more damage-inducing energy sources 112 above. For example, the one or more radiation sources may include one or more laser sources in the infrared, visible, and/or the ultraviolet range of the electromagnetic spectrum; one or more gas discharge sources; one or more incandescent radiation sources; one or more electroluminescence emitters; one or more electronic or magnetic oscillators; one or more free electron resonators, one or more x-ray emitters; and/or one or more bremsstrahlung emitters.

The system may also comprise an assembly including a substance source in contact with a surface of the boule configured to transmit the substance through the surface to the modified subsurface layer to form a modified region (e.g., interface layer). Such a configuration is shown at 104 in FIG. 8A, where the substance source (e.g., reservoir 120) is in contact with the top surface 119 of boule 115. As shown at 105A and 105B, the substance can then be transmitted through the surface 119 to subsurface damage layer 114 to form interface layer 118. As mentioned above with respect to FIG. 8B, the system may also include a bias source (e.g., one or more electrodes) for applying a bias across the interface, particularly when using an electrolyte. The electrostatic drift of ions can be used to form the interface layer or to trigger the separation via accumulation of ions.

The system can further comprise an energy source to trigger or enhance separation of a semiconductor wafer from the boule. In some embodiments, the energy source is a second radiation source configured to irradiate the interface layer and cause separation of the wide bandgap semiconductor wafer from the boule. In some embodiments, the energy source is a heat source configured to heat the interface layer and cause separation of the wide bandgap semiconductor wafer from the boule.

In some embodiments, instead of a first radiation source, the system can comprise an ion source (also shown as 112 in FIG. 8A) configured to implant ions to a subsurface layer of the boule. For example, the ion source may be an ion beam. In an ion implantation process, dopant ions can be accelerated to a high energy and directed towards the semiconductor surface. The implants penetrate the surface and come to rest at a depth dependent on the energy and angle with respect to the crystal orientation.

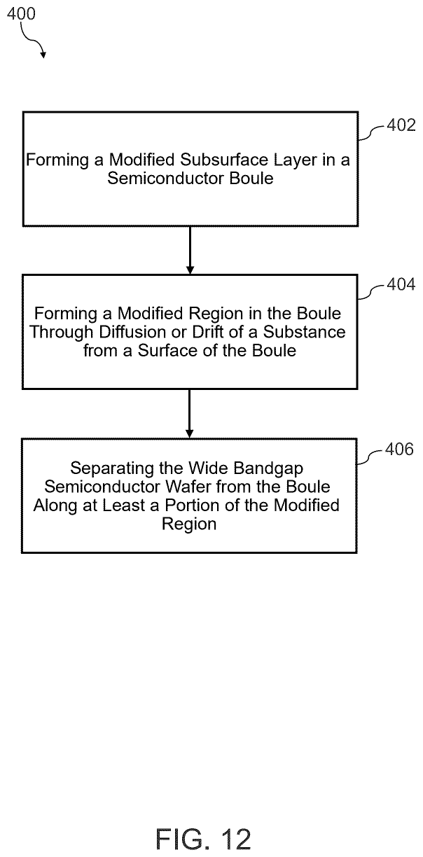

FIG. 12 depicts a flow chart diagram of an example method 400 according to aspects of the present disclosure. The method 400 depicts operations in a particular order for purposes of illustration and discussion. Those of ordinary skill in the art, using the disclosures provided herein, will understand that the various steps or operations of the method may be adapted, rearranged, omitted, include steps not illustrated, and/or modified in various ways without deviating from the scope of the present disclosure.

At 402, the method 400 optionally includes forming a modified subsurface layer in a semiconductor boule. The semiconductor boule may be made of a variety of materials. For instance, in some embodiments, the semiconductor workpiece may include silicon carbide or a group III-nitride.

In some embodiments, the modified subsurface layer may be formed by irradiating the boule with a radiation source, such as one or more laser sources that provide damage-inducing emission of radiation. In some embodiments, the modified subsurface layer may be formed by ion implantation of an impurity, such as by directing an ion beam at the boule. In some embodiments, ion implantation may be conducted at an angle with respect to the crystallographic lattice such that ion channeling of the impurity occurs.

In some embodiments, the modified subsurface layer may be a discreet layer formed between two unmodified (or relatively unmodified) semiconductor layers. In other embodiments, the modified subsurface layer may extend from the surface of the boule to a depth below the surface of the boule. Such modified subsurface layers may be formed by epitaxial growth on the surface of the boule, by diffusion of an impurity, or by material intercalation.

The modified subsurface layer may comprise voids, dopants, crystallographic 1d or 2d defects, broken bonds, recrystallized material, and/or amorphized material.

At 404, the method 400 includes forming a modified region (e.g., interface layer) in the boule through diffusion or drift of a substance from a surface of the boule. When the optional forming of a modified subsurface layer is performed prior to forming the modified region, the modified region may be formed at the modified subsurface layer. For example, the presence of the modified subsurface layer may cause the substance to accumulate in the modified layer. In such embodiments, the modified region (e.g., interface layer) may be between two unmodified semiconductor layers.

When no modified subsurface layer is formed prior to the formation of the modified region (e.g., interface layer), an interface layer may be defined by the boundary at the maximum depth to which the substance penetrates into the boule. As such, the interface layer is the boundary where a substance-impregnated region meets an unmodified region. Additionally, when a modified subsurface layer is formed that extends from the top surface of the boule to a depth below the surface, the substance may accumulate in that layer. As such the interface layer would similarly be defined by the boundary where a substance-impregnated region meets an unmodified region, which would coincide with the bottom of the modified subsurface layer.

In some embodiments, forming the modified region comprises diffusion of the substance through the top surface of the boule. For example, diffusion may be performed by contacting the surface of the boule with a gas, salt, or metal comprising the substance. Alternatively, diffusion may be performed by contacting the surface of the boule with a material containing the gas, salt, or metal comprising the substance. The material containing the gas, salt, or metal may be fluid- or ion-permeable to allow the substance to be transported to the boule. In some embodiments, for example, the substance comprises lithium, hydrogen, beryllium, boron, antimony, nitrogen, fluorine, sodium, magnesium, aluminum, phosphorus, sulfur, chlorine, iron, cobalt, nickel, HNO₃, NaOH, HF, KHF₂, NH₄F₂, NH₄F, SF₄, SF₆, NF₃, CF₄, SiF₄, Cl₂, CHF₃, IBr, ICl, I₂, H₂O₂, SiH₄, or a combination of two or more thereof.

In some embodiments, forming the modified region includes driving the drift of ions or protons by an electrostatic force. The ions may comprise lithium or fluorine ions. In some embodiments, for example, lithium ions are driven from a liquid or solid electrolyte interface to the SiC surface. Electrolytes comprising lithium can comprise LiF, LIPF₆, Li₃N—LiF, LiClO₄, LiBF₄, LiTFSI, LLZTO, LFP, LiCoO₂, Li—NMC, Li—NCA, lithium salts, or a combination of two or more thereof. The electrolyte comprising a proton can comprise acid solutions, perovskites, nafion, imidazolium, methanesulfonate, and related organic ionic plastic crystals. The interface to a metal ion source may supply other elements and their ions, such as beryllium, boron, antimony, nitrogen, fluorine, sodium, magnesium, aluminum, phosphorus, sulfur, chlorine, titanium, iron, cobalt, and nickel.

At 406, the method 400 includes separating the wide bandgap semiconductor wafer from the boule along at least a portion of the modified region (e.g., interface layer). Separation may be caused by swelling or expansion of the interface layer. In some embodiments, separating may include performing an electrochemical reaction, irradiating the interface layer, selectively heating the interface layer, and/or effecting a phase change at the interface layer. In some embodiments, separation is caused by a solid state chemical reaction, such as a reaction forming silicides, silane, or carbon oxides.

The resulting separated semiconductor wafer may have a thickness corresponding to the depth of the modified region (e.g., interface layer) below the surface of the boule. In this regard, the thickness of the wafer may be from about 0.2 μm to about 350 μm. As explained above, the diameter of the wafer may be relatively large, such as from about 150 mm to about 314 mm. However, it should be understood that the diameter or dimension (e.g., in a non-round wafer) of the wafer is not limited.

Example aspects of the present disclosure are set forth below. Any of the below features or examples may be used in combination with any of the embodiments or features provided in the present disclosure.

One example aspect of the present disclosure is directed to a method of removing a wide bandgap semiconductor wafer from a boule. The method comprises forming a modified region in the boule through diffusion or drift of a substance from a surface of the boule and separating the wide bandgap semiconductor wafer from the boule along at least a portion of the modified region.

In some examples, the modified region comprises an interface layer.

In some examples, the method further comprises forming a modified subsurface layer before forming the interface layer.

In some examples, the interface layer is formed at the modified subsurface layer.

In some examples, the modified subsurface layer comprises voids, dopants, or crystallographic 1d or 2d defects.

In some examples, the modified subsurface layer is formed using a radiation source.

In some examples, the radiation source comprises one or more laser sources that provide damage-inducing emission of radiation.

In some examples, the modified subsurface layer is formed by ion implantation.

In some examples, ion implantation comprises ion channeling of an impurity.

In some examples, ion implantation comprises gaussian ion implantation.

In some examples, the gaussian ion implantation comprises energy filtering of an ion beam

In some examples, the modified subsurface layer is formed during epitaxial growth of the boule.

In some examples, the modified subsurface layer is formed by diffusion of an impurity.

In some examples, the modified subsurface layer is formed by material intercalation.

In some examples, the modified subsurface layer comprises broken bonds, recrystallized material, or amorphized material.

In some examples, the interface layer extends from the surface of the boule from which the diffusion or drift of the material was performed to an interface between the interface layer and an unmodified semiconductor layer.

In some examples, the interface layer is between two unmodified semiconductor layers.

In some examples, forming the interface layer comprises diffusion of the substance.

In some examples, diffusion is performed by contacting the surface of the boule with a gas, salt, or metal comprising the substance.

In some examples, diffusion is performed by contacting the surface of the boule with material containing a gas, salt, or metal comprising the substance.

In some examples, the material containing the gas, salt, or metal is fluid- or ion-permeable.

In some examples, the substance comprises lithium, hydrogen, beryllium, boron, antimony, titanium, nitrogen, fluorine, sodium, magnesium, aluminum, phosphorus, sulfur, chlorine, iron, cobalt, nickel, HNO₃, NaOH, HF, KHF₂, NH₄F₂, NH₄F, SF₄, SF₆, NF₃, CF₄, SiF₄, Cl₂, CHF₃, IBr, ICl, I₂, H₂O₂, SiH₄, or a combination of two or more thereof.

In some examples, forming the interface layer comprises driving the drift of ions or protons by an electrostatic force.

In some examples, the ions comprise lithium ions.

In some examples, the lithium ions are driven from a liquid or solid electrolyte interface to the SiC surface.

In some examples, the electrolyte comprises LiF, LIPF₆, Li₃N—LiF, LiClO₄, LiBF₄, LiTFSI, LLZTO, LFP, LiCoO₂, Li—NMC, Li—NCA, or a combination of two or more thereof.

In some examples, forming the interface layer comprises thermal diffusion.

In some examples, separating is caused by swelling of the modified region.

In some examples, separating comprises performing an electrochemical reaction.

In some examples, separating comprises irradiating the modified region.

In some examples, separating comprises selectively heating the modified region.

In some examples, separating comprises effecting a phase change at the modified region.

In some examples, separating is caused by a solid state chemical reaction.

In some examples, the solid state chemical reaction forms silicides, carbides, silane, or carbon oxides.

In some examples, the wide bandgap semiconductor wafer comprises silicon carbide.

In some examples, the wide bandgap semiconductor wafer comprises a group III-nitride.

In some examples, the wide bandgap semiconductor wafer has a diameter from about 150 mm to about 314 mm.

In some examples, the wide bandgap semiconductor wafer has a thickness from about 0.2 μm to about 350 μm.

Another example aspect of the present disclosure is directed to a system for separating a wide bandgap semiconductor wafer from a boule. The system comprises a radiation source configured to provide a damage-inducing emission and a substance source in contact with a surface of the boule configured to transmit the substance through the surface to the subsurface damage layer to form a modified region. The damage-inducing emission is configured to induce a subsurface damage layer in a boule.

In some examples, the radiation source comprises one or more laser sources.

In some examples, the subsurface damage layer comprises broken bonds, recrystallized material, or amorphized material.

In some examples, the substance source comprises a gas, salt, or metal comprising the substance.

In some examples, the substance source comprises a fluid-or ion-permeable material containing material comprising the gas, salt, or metal.

In some examples, the substance comprises lithium, hydrogen, beryllium, boron, antimony, titanium, nitrogen, fluorine, sodium, magnesium, aluminum, phosphorus, sulfur, chlorine, iron, cobalt, nickel, HNO3, NaOH, HF, KHF2, NH4F2, NH4F, SF4, SF6, NF3, CF4, SiF4, Cl2, CHF3, IBr, ICl, I2, H2O2, SiH4, or a combination of two or more thereof.

In some examples, the substance comprises ions or protons.

In some examples, the system further comprises a bias source configured to drive the ions through the surface by an electrostatic force.

In some examples, the ions comprise lithium ions.

In some examples, the substance source comprises an electrolyte comprising lithium.

In some examples, the electrolyte comprising lithium comprises LiF, LIPF6, Li3N—LiF, LiClO4, LiBF4, LiTFSI, LLZTO, LFP, LiCoO2, Li—NMC, Li—NCA, or a combination of two or more thereof.

In some examples, the system further comprises a second radiation source configured to irradiate the modified region and cause separation of the wide bandgap semiconductor wafer from the boule.

In some examples, the system further comprises a heat source configured to heat the modified region and cause separation of the wide bandgap semiconductor wafer from the boule.

In some examples, the wide bandgap semiconductor wafer comprises silicon carbide.

In some examples, the wide bandgap semiconductor wafer comprises a group III-nitride.

In some examples, the wide bandgap semiconductor wafer has a diameter from about 150 mm to about 314 mm.

In some examples, the wide bandgap semiconductor wafer has a thickness from about 0.2 μm to about 350 μm.

Another example aspect of the present disclosure is directed to a system for separating a wide bandgap semiconductor wafer from a boule. The system comprises an ion source configured to implant ions to a subsurface layer of a boule; and a substance source in contact with a surface of the boule configured to transmit the substance through the surface to the subsurface layer to form a modified region.

In some examples, the ion source comprises an ion beam configured to implant the ions by ion channeling.

In some examples, the substance source comprises a gas, salt, or metal comprising the substance.

In some examples, the substance source comprises a fluid- or ion-permeable material containing material comprising the gas, salt, or metal.

In some examples, the substance comprises lithium, hydrogen, beryllium, boron, antimony, titanium, nitrogen, fluorine, sodium, magnesium, aluminum, phosphorus, sulfur, chlorine, iron, cobalt, nickel, HNO3, NaOH, HF, KHF2, NH4F2, NH4F, SF4, SF6, NF3, CF4, SiF4, Cl2, CHF3, IBr, ICl, I2, H2O2, SiH4, or a combination of two or more thereof.

In some examples, the substance comprises ions or protons.

In some examples, the system further comprises a bias source configured to drive the ions through the surface by an electrostatic force.

In some examples, the ions comprise lithium ions.

In some examples, the substance source comprises an electrolyte comprising lithium.

In some examples, the electrolyte comprising lithium comprises LiF, LIPF6, Li3N—LiF, LiClO4, LiBF4, LiTFSI, LLZTO, LFP, LiCoO2, Li—NMC, Li—NCA, or a combination of two or more thereof.

In some examples, the system further comprises a radiation source configured to irradiate the modified region and cause separation of the wide bandgap semiconductor wafer from the boule.

In some examples, the system further comprises a heat source configured to heat the modified region and cause separation of the wide bandgap semiconductor wafer from the boule.

In some examples, the wide bandgap semiconductor wafer comprises silicon carbide.

In some examples, the wide bandgap semiconductor wafer comprises a group III-nitride.

In some examples, the wide bandgap semiconductor wafer has a diameter from about 150 mm to about 314 mm.

In some examples, the wide bandgap semiconductor wafer has a thickness from about 0.2 μm to about 350 μm.

Another example aspect of the present disclosure is directed to an assembly. The assembly comprises a boule having a modified subsurface layer and a substance source in contact with a surface of the boule configured to transmit the substance through the surface to the modified subsurface layer to form a modified region.

In some examples, the modified subsurface layer comprises broken bonds, recrystallized material, or amorphized material.

In some examples, the modified subsurface layer comprises an ion-implanted layer.

In some examples, the modified subsurface layer comprises a laser-induced damage layer.

In some examples, the substance source comprises a gas, salt, or metal comprising the substance.

In some examples, the substance source comprises a fluid-or ion-permeable material containing material comprising the gas, salt, or metal.

In some examples, the substance comprises lithium, hydrogen, beryllium, boron, antimony, titanium, nitrogen, fluorine, sodium, magnesium, aluminum, phosphorus, sulfur, chlorine, iron, cobalt, nickel, HNO3, NaOH, HF, KHF2, NH4F2, NH4F, SF4, SF6, NF3, CF4, SiF4, Cl2, CHF3, IBr, ICl, I2, H2O2, SiH4, or a combination of two or more thereof.

In some examples, the substance comprises ions or protons.

In some examples, the assembly further comprises a bias source configured to drive the ions through the surface by an electrostatic force.

In some examples, the ions comprise lithium ions.

In some examples, the substance source comprises an electrolyte comprising lithium.

In some examples, the electrolyte comprising lithium comprises LiF, LIPF6, Li3N—LiF, LiClO4, LiBF4, LiTFSI, LLZTO, LFP, LiCoO2, Li—NMC, Li—NCA, or a combination of two or more thereof.

In some examples, the assembly further comprises a radiation source configured to irradiate the modified region and cause separation of the wide bandgap semiconductor wafer from the boule.

In some examples, the assembly further comprises a heat source configured to heat the modified region and cause separation of the wide bandgap semiconductor wafer from the boule.

In some examples, the wide bandgap semiconductor wafer comprises silicon carbide.

In some examples, the wide bandgap semiconductor wafer comprises a group III-nitride.

In some examples, the wide bandgap semiconductor wafer has a diameter from about 150 mm to about 314 mm.

In some examples, the wide bandgap semiconductor wafer has a thickness from about 0.2 μm to about 350 μm.

Another example aspect of the present disclosure is directed to a semiconductor wafer comprising silicon carbide. The semiconductor wafer comprises a diffused impurity. A concentration of the diffused impurity is non-uniform along a thickness of the semiconductor wafer. A ratio of the concentration of the diffused impurity in one major surface region of the semiconductor wafer to the concentration of the diffused impurity in a central region is about 10 or more.

In some examples, the impurity comprises lithium, hydrogen, beryllium, boron, antimony, titanium, nitrogen, fluorine, sodium, magnesium, aluminum, phosphorus, sulfur, chlorine, iron, cobalt, nickel, HNO3, NaOH, HF, KHF2, NH4F2, NH4F, SF4, SF6, NF3, CF4, SiF4, Cl2, CHF3, IBr, ICl, I2, H2O2, SiH4, or a combination of two or more thereof.

In some examples, the impurity comprises ions or protons.

In some examples, the ions comprise lithium ions.

In some examples, the impurity comprises silicides, carbides, silane, or carbon oxides.

In some examples, the ratio of the concentration of the diffused impurity in one major surface region of the semiconductor wafer to the concentration of the diffused impurity in the central region is about 20 or more.

In some examples, the semiconductor wafer has a diameter of about 150 millimeters.

In some examples, the semiconductor wafer has a diameter of about 200 millimeters.

In some examples, the semiconductor wafer has a diameter of about 300 millimeters.

In some examples, the semiconductor wafer has a thickness from about 0.2 μm to about 350 μm.

Another example aspect of the present disclosure is directed to a semiconductor wafer comprising silicon carbide. The semiconductor wafer comprises an impurity comprising lithium, beryllium, fluorine, sodium, magnesium, sulfur, antimony, titanium, chlorine, iron, cobalt, nickel, HNO3, NaOH, HF, KHF2, NH4F2, NH4F, SF4, SF6, NF3, CF4, SiF4, Cl2, CHF3, IBr, ICl, I2, H2O2, SiH4, lithium ions, fluorine ions, silicides, carbides, silanes, carbon oxides, protons, or a combination of two or more thereof.

In some examples, the impurity further comprises hydrogen.

In some examples, the semiconductor wafer has a diameter of about 150 millimeters.

In some examples, the semiconductor wafer has a diameter of about 200 millimeters.

In some examples, the semiconductor wafer has a diameter of about 300 millimeters.

In some examples, the semiconductor wafer has a thickness from about 0.2 μm to about 350 μm.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method of removing a wide bandgap semiconductor wafer from a boule, the method comprising:
forming a modified region in the boule through diffusion or drift of a substance from a surface of the boule; and
separating the wide bandgap semiconductor wafer from the boule along at least a portion of the modified region.

2. The method of claim 1, wherein the modified region comprises an interface layer.

3. The method of claim 2, further comprising forming a modified subsurface layer before forming the interface layer.

4. The method of claim 3, wherein the interface layer is formed at the modified subsurface layer.

5. The method of claim 3, wherein the modified subsurface layer is formed (a) using a radiation source, (b) by ion implantation, (c) during epitaxial growth of the boule, (d) by diffusion of an impurity, or (e) by material intercalation.

6. The method of claim 2, wherein the interface layer extends from the surface of the boule from which the diffusion or drift of the substance was performed to an interface between the interface layer and an unmodified semiconductor layer.

7. The method of claim 2, wherein the interface layer is between two unmodified semiconductor layers.

8. The method of claim 2, wherein forming the interface layer comprises diffusion of the substance.

9. The method of claim 8, wherein diffusion is performed by contacting the surface of the boule with a gas, salt, or metal comprising the substance.

10. The method of claim 8, wherein diffusion is performed by contacting the surface of the boule with material containing a gas, salt, or metal comprising the substance.

11. The method of claim 8, wherein the substance comprises lithium, hydrogen, beryllium, boron, antimony, titanium, nitrogen, fluorine, sodium, magnesium, aluminum, phosphorus, sulfur, chlorine, iron, cobalt, nickel, HNO₃, NaOH, HF, KHF₂, NH₄F₂, NH₄F, SF₄, SF₆, NF₃, CF₄, SiF₄, Cl₂, CHF₃, IBr, ICl, I₂, H2O2, SiH₄, or a combination of two or more thereof.

12. The method of claim 2, wherein forming the interface layer comprises driving the drift of ions or protons by an electrostatic force.

13. The method of claim 12, wherein the ions comprise lithium ions.

14. The method of claim 13, wherein the lithium ions are driven from a liquid or solid electrolyte interface to the surface.

15. The method of claim 14, wherein the electrolyte comprises LiF, LIPF₆, Li₃N—LiF, LiClO₄, LiBF₄, LiTFSI, LLZTO, LFP, LiCoO₂, Li—NMC, Li—NCA, or a combination of two or more thereof.

16. The method of claim 2, wherein forming the interface layer comprises thermal diffusion.

17. The method of claim 1, wherein separating (a) is caused by swelling of the modified region, (b) comprises performing an electrochemical reaction, (c) comprises irradiating the modified region, (d) comprises selectively heating the modified region, (e) comprises effecting a phase change at the modified region, or (f) is caused by a solid state chemical reaction.

18. The method of claim 1, wherein the wide bandgap semiconductor wafer comprises silicon carbide or a group III-nitride.

19. A system for separating a wide bandgap semiconductor wafer from a boule, the system comprising:
a radiation source configured to provide a damage-inducing emission, wherein the damage-inducing emission is configured to induce a subsurface damage layer in a boule; and
a substance source in contact with a surface of the boule configured to transmit the substance through the surface to the subsurface damage layer to form a modified region.

20. A semiconductor wafer comprising silicon carbide, the semiconductor wafer comprising a diffused impurity, wherein a concentration of the diffused impurity is non-uniform along a thickness of the semiconductor wafer, wherein a ratio of the concentration of the diffused impurity in one major surface region of the semiconductor wafer to the concentration of the diffused impurity in a central region is about 10 or more.
